(19) United States
(12) Patent Application Publication
(10) Pub. No.: US 2008/0264680 A1
(43) Pub. Date: Oct. 30, 2008

(54) Voltage-Operated Layer Arrangement

(75) Inventors: Herbert Friedrich Borner, Aachen (DE); Edward Willem Albert Young, Maastricht (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/089,240

(22) PCT Filed: Sep. 27, 2006
(86) PCT No.: PCT/IB2006/053509

§ 371 Date: Apr. 4, 2008

(30) Foreign Application Priority Data
Oct. 7, 2005 (EP) 05109344.1

(51) Int. Cl. H05K 1/03; H05K 3/10

(52) U.S. Cl. 174/256; 29/846

(57) ABSTRACT

A voltage-operated layer arrangement having a substrate (1), a layered structure (2, 3, 4) that is applied to the substrate and comprises at least one continuous functional layer (2) that is arranged between a first (3) and a second (4) electrode, and a magnesium covering layer (15) that is applied to the second electrode (4) arranged on the side of the layered structure remote from the substrate, for the encapsulation of one or more particles (13).

The invention relates to a voltage-operated layer arrangement having a functional layer, and covering layers for the electrical passivation of the layer arrangement, and to a method of producing such a layer arrangement.

There are a large number of known voltage-operated layer arrangements that comprise a plurality of thin layers or films and that have a functional layer for the application of an operating voltage, such as for example computer chips, thin-film components, or electroluminescent arrangements having inorganic or organic electroluminescent layers. These layer arrangements comprise a layered structure having a functional layer, which functional layer is arranged between an anode and a cathode for the application of an operating voltage across the functional layer. The functional layers are intended for example for the emission of light, to act as dielectric layers or to be used for other applications. The layered structure is typically applied to a substrate. The typical thicknesses of the layered structure may vary between a few hundred nm and a few tens of μm. The typical voltages applied to the functional structure are between a few volts and a few tens of volts. Leakage currents or short-circuits between the anode and cathode have an adverse effect on the life of such a layer arrangement. Depending on the intensity and duration of the leakage current and/or short-circuit, a layer arrangement of this kind may even be destroyed.

It is precisely during the process of producing large-area layer arrangements of a few square centimeters or more that the presence of particles, of dust for example, is unavoidable. Technical measures, such as for example clean rooms of appropriate particle classes, are not able to prevent particles from being present during the production of the layered structure but are only able to reduce their presence, which they do at the cost of considerable expenditure. The particles that settle on the substrate or, during the production process, on a layer of the layered structure cause, as a layer is being produced, hole defects the nature of whose edges is undefined. Only part of the structure of the layer, or even nothing whatever of it, is present in such holes. When an operated voltage is applied, such defects may result in unacceptable leakage currents and short-circuits between the cathode and anode and are thus a major cause of defective functional layers and hence of defective layer arrangements. The European patent application numbered EP 04104385.2 describes, taking as an example large-area layer arrangements having an organic functional layer for the emission of light (OLEDs), the electrical passivation of such layer defects by means of a chemically inert dielectric liquid. So that the layer arrangement, and hence the particle and the hole defect caused by it as well, are completely enveloped by the passivating liquid, the layer arrangement is encapsulated mechanically in a sort of hood. Precisely with large-area layer arrangements, this hood causes a larger overall depth, is a factor that imposes restrictions on design and mobility for layer arrangements on mechanically flexible substrates and, in the production of voltage-operated layer arrangements, requires various additional process steps for the fitting of the hood and the filling of the hood with the passivating liquid.

It is therefore an object of the present invention to provide a voltage-operated layer arrangement having electrical passivation, which voltage-operated layer arrangement is of low overall depth, maintains the functionality of flexible substrates, and makes it possible for the production process to be simplified.

This object is achieved by a voltage-operated layer arrangement having a substrate, a layered structure that is applied to the substrate and comprises at least one continuous functional layer that is arranged between a first and a second electrode, and a magnesium covering layer that is applied to the second electrode arranged on the side of the layered structure remote from the substrate, for the encapsulation of one or more particles clinging to one or more layers of the layered structure. What is meant by encapsulation of the particles in this case is a magnesium covering layer in the region of the particles that has a continuous surface not containing any holes leading to the layered structure situated beneath it. By using a magnesium covering layer, it is possible to avoid mechanical encapsulation devices such as for example containers made of metal or glass that contain an electrical passivating liquid, and this results in a reduction in the overall depth of the voltage-operated layer arrangement. However, to exclude water, capsulation by a suitable cover may still be required. What is more, in the layer arrangement that is electrically passivated in accordance with the invention flexible substrates keep their functionality.

Reliable electrical passivation is obtained even with a magnesium covering layer of a thickness of at least 5 nm. For reasons relating to the adhesion of the layer to the layered structure situated beneath it, it is advantageous if the magnesium covering layer is of a thickness less than 100 nm.

In another embodiment, a protective layer is applied to the magnesium covering layer. This prevents any detachment of the magnesium covering layer during the life of the layer arrangement. A suitable material for a layer protective of adhesion of this kind is a metal or an organic material.

In another embodiment, the functional layer is an electroluminescent layer. Layer arrangements having electroluminescent layers (LEDs) for emitting light constitute thin light sources of high luminance.

In another embodiment, the electroluminescent layer comprises an organic material. Layer arrangements having organic electroluminescent layers (organic LEDs, or OLEDs) for the emission of light represent inexpensive thin light sources of large area that can be applied even to flexible substrates. Known as electroluminescent organic materials are polymers or what are called SMOLED (small molecule organic light emitting device) materials.

The invention also relates to a method of producing a layer arrangement for the application of an operating voltage as claimed in claim 1, which method comprises the steps of

producing on the substrate the layered structure comprising the continuous functional layer, which continuous functional layer is produced by at least one conformal, first coating process,

application of the second electrode, and

application of the magnesium covering layer, by means of a second coating process, to the second electrode, using one or more deflecting elements that enable a part of the magnesium material to impact on the second electrode at a small angle.

What is meant by a directional coating process is a process in which the material to be applied moves substantially in a straight line from the source and to the substrate that is to be coated. A characteristic of such methods is non-coated (shadowed or masked) regions situated behind edges, masks etc. that are arranged in the region of space between the source and substrate. In contrast to this, what are referred to as conformal coating processes are ones in which there is appreciably less shadowing than in the directional coating processes.

In one embodiment of the method, the conformal coating process for producing the continuous functional layer comprises at least one method from the group comprising OVPD, printing processes and in-line coating processes using linear sources. In a further embodiment, the second coating process is a thermal vapor deposition process. OVPD means “organic vapor phase deposition”. In this case the material to be applied is transported onto the substrate in a flow of gas at low pressure (approx. 0.1 mbar) and high temperature (approx. 300°). In-line coating process using linear sources means vacuum coating systems in which a plurality of evaporating sources are arranged closely adjacent to one another in a line, the substrate being fed transversely along this line of evaporators.

These and other aspects of the invention are apparent from and will be elucidated with reference to the embodiments described hereinafter.

In the drawings:

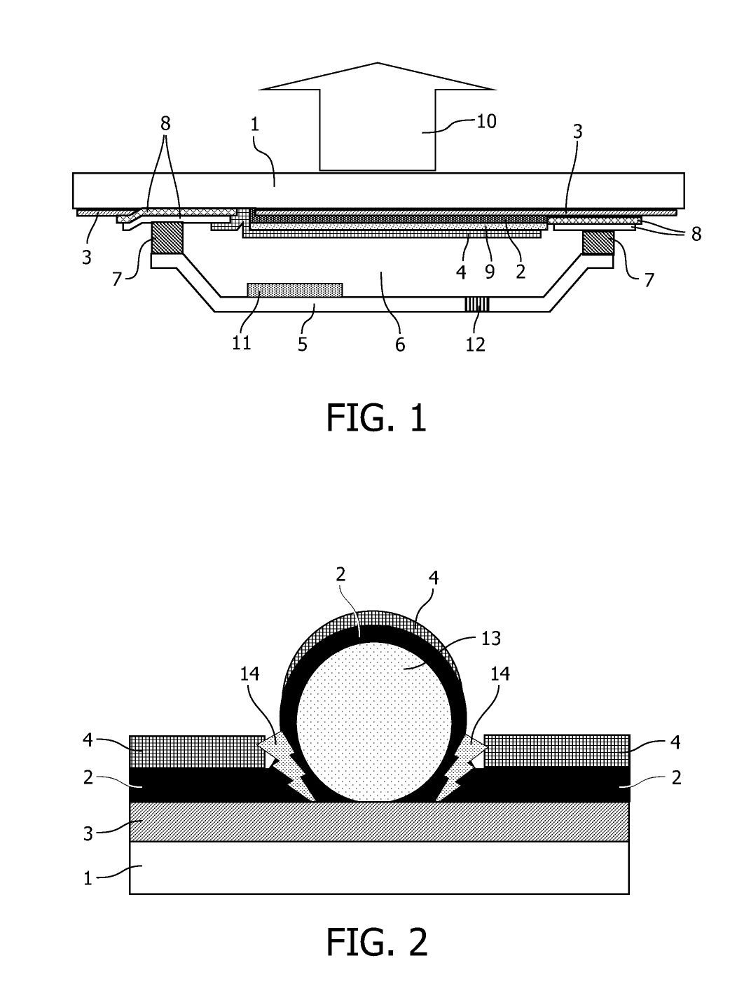

FIG. 1 is a side view of a prior art voltage-operated layer arrangement, an encapsulated organic LED being taken as an example.

FIG. 2 is a side view of a layer defect caused by a dust particle.

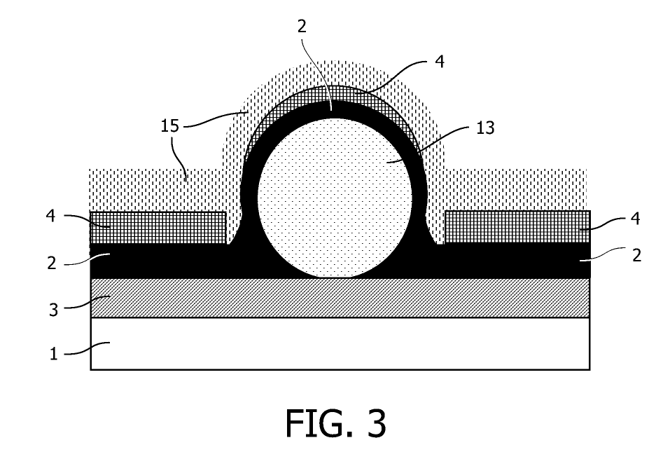

FIG. 3 is a side view of a voltage-operated layer arrangement according to the invention having a layer defect caused by a dust particle

FIG. 1 is a side view of an encapsulated voltage-operated layer arrangement, with an organic LED being taken as an example. The layered structure of the electroluminescent arrangement comprises a thin organic layer stack having a luminescent layer 2 (such as doped tris-(8-hydroxyquinolinato)aluminum for example) of a typical thickness in the 100 nm range, which luminescent layer 2 is arranged between two electrodes (such as for example a first electrode acting as an anode 3 and a second electrode acting as a cathode 4), at least one of which is transparent. What is usually used as a transparent conductive material is indium tin oxide (ITO). What is used as a non-transparent electrode is conductive material, usually a layer of metal, of a thickness of the order of magnitude of 100 nm. There are however also arrangements in which both electrodes are transparent. The layered structured is applied to a substrate 1 and emits the luminescent light 10 through the substrate 1. In the present case the anode 3 comprises an ITO layer and the cathode 4 a layer of aluminum. The layered structure may also be applied to the substrate in the reverse order. Arranged between the organic luminescent layer 2 and the anode 4 there is generally a layer having p-type conductivity, typically alpha-NPD (N, N′-di(naphthalene-2-yl)-N, N′-diphenyl benzidine), of a thickness of approximately 50 nm. Between the cathode 4 and the organic luminescent layer 2, there is usually a thin electron-injecting layer 9 made of a material having a low work function, such as for example lithium, cesium or barium, that is important for good injection of electrons into the luminescent layer. For the purpose, amongst others, of receiving a chemically inert dielectric liquid for the electrical passivation of the layered structure having layer defects caused by particles, the voltage-operated layer arrangement is provided with an encapulsating arrangement comprising a cover 5 that, by means of adhesive-bonded connections 7, encloses the layered structure having the organic luminescent layer 2 and is solidly connected thereto. For the application of an operating voltage to the layered structure, conductor tracks 8 and 3 are run out of the encapsulation. A sealable opening 12 may for example be used for filling the volume of space 6 with the chemically inert dielectric liquid for electrical passivation. A getter material 11 may, in addition, be arranged inside the encapsulation to reduce the proportion of moisture/water within the volume of space 6.

The design shown in FIG. 1 is only one example of voltage-operated layer arrangements. Layer properties such as transparency and/or reflectivity are of no relevance in non-optical applications. For other applications, the sequence of layers and the materials of the layers may be partly or entirely different from the sequence of layers and the material of the layers shown in FIG. 1. However, for all voltage-operated applications equally, the problem exists that, during the process of producing a layered structure comprising one or more thin layers or films, the presence of particles such as for example dust particles on the substrate or on a layer of the layered structure may be the cause of layer defects, which defects may in turn lead to an increased field strength within the layered structure between the cathode and anode and hence to a leakage current and/or a short-circuit and then to failure of the voltage-operated layer arrangement.

A voltage-operated layer arrangement, such as that of an OLED arrangement for example, comprises individual thin layers of which a high proportion are produced by dry, directional coating processes such as for example vacuum vapor deposition and/or sputtering. In such directional coating processes, the presence of particles 13, such as dust particles for example, leads to the substrate or the part of the layered structure that is to be coated being placed in shadow and thus leads to layer defects, as shown in FIG. 2. The dimensions of the particles concerned are usually appreciably larger than the thicknesses of the individual layers. Due to the shadowing during the coating process, none, or only a part, of the layers that will subsequently be present away from the layer defects is present within the layer defects. The size and shape of the layer defects depend on the position and geometry of the particle and on the time as from which the particle was present during the production of the thin layer on the growing layered structure. For an OLED arrangement for example there is, for a typical operating voltage of 3 to 10 V between the electrodes and a typical electrode spacing of 100 nm, a field of 30-100 kV/mm between the electrodes. The edges of material around a particle in the material of the electrode, which electrode is arranged on the side of the layered structure remote from the substrate, produce substantially higher field strengths locally due to the very small radius of curvature of the edges. A leakage current and/or a flashover 14 between the cathode 4 and anode 3 leads to an uncontrolled flow of current. This process, which is usually self-amplifying over the duration of the flow of current, results in the layer arrangement being destroyed. The occurrence of this process, in OLED arrangements for example, does not depend on whether, depending on the form taken by the EL structure, there are one or more organic layers situated between the anode and cathode.

The probability of layer defects increases with the area of the voltage-operated layered arrangement. However, it is precisely in the case of organic electroluminescent arrangements (OLEDs) that it is an advantage that these arrangements can be produced in a form in which they cover a large area. However, large-area OLED arrangements can only be produced with a low failure rate if flashovers between the electrodes are avoided. The electrical passivation according to the invention of such layer defects within the voltage-operated layer arrangement (see FIG. 3) represents an effective and inexpensive solution that overcomes other disadvantages of the prior art, such as for example a high overall depth, and maintains the functionality of flexible substrates.

In the present case, a voltage-operated layer arrangement according to the invention is produced by coating processes that make it possible for a layered structure having a continuous functional layer to be produced. The material of the functional layer 2 is deposited in this case by a process that ensures that the particles 13 that are clinging to the substrate 1 or a layer 3 situated below the functional layer 2 are enclosed. Functional layers 2 for the emission of light, such as for example organic electroluminescent layers, are typically produced by processes of this kind such as OVPD, printing processes or coating processes using linear sources.

What is meant by OVPD is organic vapor phase deposition. In this case the material to be applied is transported onto the substrate in a flow of gas at low pressure (approx. 0.1 mbar) and high temperature (approx. 300°).

What are meant by linear sources are vacuum coating systems in which a plurality of evaporating sources are arranged closely adjacent to one another in a line, the substrate being fed transversely along this line of evaporators.

The electrode 4 is then applied to the functional layer 2. With the usual electrode materials such as for example aluminum, a continuous electrode layer 4 cannot be produced even with conformal processes that are suitable for the application of aluminum, due to the shadowing by the particle 13, the diameter of which is, as a rule, orders of magnitude greater than the layer thickness of the electrode 4.

As a result of the material edges in the electrode material, the field strengths 14 are considerably higher locally around the particle 13 due to the very small radius of curvature of the edges, and to avoid these higher field strengths, a magnesium covering layer 15 is applied, in accordance with the invention, to the electrode material. Magnesium is distinguished in this case by its surprising deposition properties. Magnesium adheres only slightly to surfaces, which is why, in a coating system, a high proportion thereof impacts on the walls and is reflected at a different angle of flight. This results in complete prevention of any shadowing (meaning regions of the substrate that are not coated due to masking off of the material being applied by objects, such as particles for example, which are situated in the direct line between the source and the substrate) by particles 13, because part of the magnesium material released by the source of material impacts on the material of the second electrode 4 at small angles relative to the surface of the second electrode 4 after a plurality of reflections from walls or from deflector elements, such as deflector plates for example, which are specially fitted in the coating apparatus. Surprisingly, the surface of the substrate is given an uninterrupted cover in this case, with edges at which excessively high field strengths occur due to the small radius of curvature being avoided. Other metals, such as aluminum for example, adhere considerably more strongly to the surfaces and do not, therefore, provide an uninterrupted cover over particles.

For this purpose, magnesium may be thermally evaporated from a crucible, typically made of molybdenum. The evaporating source, such as a crucible for example, is arranged close to the voltage-operated layer arrangement that is to be coated. In the thermal evaporation, the magnesium atoms are able to reach the layer arrangement either by the direct path from the source, at large angles to the surface of the second electrode 4, or after a plurality of reflections from the walls or deflector plates in the coating system, at small angles to the surface of the second electrode 4. In this way, a continuous layer 15 of magnesium grows, without shadowing, on surfaces of any desired shape, i.e. including on particles 13 of irregular shapes. The vacuum in the evaporation system should be better than 10⁻⁵ mbar, to enable a metal layer 15 made of magnesium and in electrical contact with the second electrode 4 to be produced for the purpose of electrical passivation in the region of the particles 13.

What are required for a continuous electrically conductive layer 15 of magnesium are thicknesses of at least 5 nm. Due to the low adhesive capacity of the magnesium material, magnesium layers 15 of a thickness of more than 100 nm are subject to problems relating to adhesion on the second electrode 4 over their life. To rule out adhesion problems in general and/or to enable magnesium layers of thicknesses above 100 nm to be used, the layer arrangement having the magnesium covering layer 15 may be coated with an additional protective layer having good adhesive properties comprising a metal or an organic material, such as for example a UV-curing material.

A different approach to achieving the object underlying the present invention, namely reducing the number of layer defects by means of very costly clean-room technology, would mean a sharp rise in production costs and is unable to entirely prevent layer defects from occurring in, precisely, the case of large-area EL arrangements.

The present method of electrical passivation is not dependent on the nature of the use that is made of the functional layer, be it as a light source or for other purposes.

The embodiments that have been elucidated by reference to the drawings and in the description merely represent examples of the electrical passivation of a voltage-operated layer arrangement and are not to be construed as limiting the claims to these examples. Alternative embodiments for other voltage-operated layer arrangements having functional layers for other purposes which are likewise covered by the scope of protection afforded by the claims will also be readily apparent to the person skilled in the art. The numbering of the dependent claims is not intended to imply that other combinations of the claims do not also constitute advantageous embodiments of the invention.

1. A voltage-operated layer arrangement having
a substrate (1),
a layered structure (2, 3, 4) that is applied to the substrate and comprises at least one continuous functional layer (2) that is arranged between a first (3) and a second (4) electrode, and
a magnesium covering layer (15) that is applied to the second electrode (4) arranged on the side of the layered structure remote from the substrate, for the encapsulation of one or more particles (13) clinging to one or more layers of the layer arrangement.

2. A voltage-operated layer arrangement as claimed in claim 1, characterized in that the magnesium covering layer (15) is of a thickness of at least 5 nm.

3. A voltage-operated layer arrangement as claimed in claim 2, characterized in that the magnesium covering layer (15) is of a thickness less than 100 nm.

4. A voltage-operated layer arrangement as claimed in claim 1, characterized in that a layer protective of adhesion is applied to the magnesium covering layer (15).

5. A voltage-operated layer arrangement as claimed in claim 4, characterized in that the material of the layer protective of adhesion is a metal or an organic material.

6. A voltage-operated layer arrangement as claimed in claim 1, characterized in that the functional layer (2) is an electroluminescent layer.

7. A voltage-operated layer arrangement as claimed in claim 6, characterized in that the electroluminescent layer comprises an organic material.

8. A method of producing a voltage-operated layer arrangement as claimed in claim 1, which method comprises the steps of
producing on the substrate (1) the layered structure (2, 3, 4) comprising the continuous functional layer (2), which continuous functional layer (2) is produced by at least one conformal, first coating process,
application of the second electrode (4), and
application of the magnesium covering layer (15), by means of a second coating process, to the second electrode (4), using one or more deflecting elements that enable a part of the magnesium material to impact on the second electrode (4) at a small angle.

9. A method as claimed in claim 8, characterized in that the conformal, first coating process for producing the continuous functional layer (2) comprises at least one method from the group comprising OVPD, printing processes and in-line coating processes using linear sources.

10. A method as claimed in claim 8, characterized in that the second coating process is a thermal vapor deposition process.
